(19) United States
(12) Patent Application Publication
(10) Pub. No.: US 2025/0309145 A1
(43) Pub. Date: Oct. 2, 2025

(54) STACKED CIRCUIT COMPONENT DEVICES EMBEDDED IN PACKAGE SUBSTRATES

(71) Applicant: Intel Corporation, Santa Clara, CA (US)

(72) Inventors: Srinivas Venkata Ramanuja Pietambaram, Chandler, AZ (US); Aleksandar Aleksov, Chandler, AZ (US); Gang Duan, Chandler, AZ (US); Brandon Christian Marin, Gilbert, AZ (US)

(73) Assignee: Intel Corporation, Santa Clara, CA (US)

(21) Appl. No.: 18/619,726

(22) Filed: Mar. 28, 2024

(51) Int. Cl. H01L 23/58; H01F 27/06; H01F 27/40; H01G 4/224; H01G 4/40; H01L 23/00; H01L 23/13; H01L 25/16

(52) U.S. Cl. CPC H01L 23/58; H01F 27/06; H01F 27/40; H01G 4/224; H01G 4/40; H01L 23/13; H01L 25/16; H01L 24/32; H01L 2224/32265; H01L 2924/19041; H01L 2924/19042; H01L 2924/19104

(57) ABSTRACT

In embodiments herein, multiple circuit component assemblies are coupled together in a device, which is embedded within a core layer of a substrate. Each circuit component assembly includes a respective layer of conductive traces that are oriented in a planar direction that is substantially orthogonal to a planar direction of the core layer.

### BACKGROUND

Circuit components, e.g., power delivery components such as inductors and capacitors, may be embedded within a core of a package substrate for an integrated circuit package. However, embedding components has proven to be difficult due to various factors, such as thickness mismatches between the core and the component, which can lead to tilting or shifting of the component within the cavity. In addition, as power delivery requirements increase (e.g., for higher performance applications), higher inductance and capacitance values may be needed. However, embedding multiple circuit components within a core layer to achieve the needed inductance and capacitance values may prove very difficult or impossible.

### BRIEF DESCRIPTION OF THE DRAWINGS

FIG. 1 illustrates an example package substrate with an embedded stacked circuit component device in a core layer.

FIG. 2 illustrates an example multi-die integrated circuit package with an embedded stacked circuit component device in a core layer.

FIGS. 3A-3E illustrate an example process of fabricating a circuit component assembly that can be included in a stacked circuit component device.

FIG. 4 illustrates the stacked circuit component device produced by the process of FIG. 3 embedded in a core layer of an integrated circuit package substrate.

FIGS. 5A-5E illustrate an example process of fabricating buildup layers on the core layer in FIG. 4.

FIGS. 6A-6B illustrate example embodiments of stacked circuit component devices with different traces of different formations embedded within an opening in a core layer of an integrated circuit package substrate.

FIG. 7 illustrates an example stacked circuit component device in accordance with embodiments of the present disclosure.

FIG. 8 illustrates another example stacked circuit component device in accordance with embodiments of the present disclosure.

FIG. 9 illustrates yet another example stacked circuit component device in accordance with embodiments of the present disclosure.

FIGS. 10A-10B illustrate example systems that may incorporate the architectures described herein.

FIG. 11 is a top view of a wafer and dies that may be included in a microelectronic assembly, in accordance with any of the embodiments disclosed herein.

FIG. 12 is a cross-sectional side view of an integrated circuit device that may be included in a microelectronic assembly, in accordance with any of the embodiments disclosed herein.

FIG. 13 is a block diagram of an example electrical device that may include a microelectronic assembly, in accordance with any of the embodiments disclosed herein.

### DETAILED DESCRIPTION

Embodiments of the present disclosure relate to stacked circuit component devices embedded within the core layer of a package substrate. The embedded stacked circuit component devices may include a number of passive components and/or active component assemblies. For example, the embedded stacked circuit component devices of the present disclosure may include any number of component assemblies that each include deep trench capacitors (DTCs), or metal-in-metal (MIM) capacitors, magnetic inductor arrays (MIAs), or transistors. The embedded stacked circuit component devices of the present disclosure may allow for higher densities of circuit components to be embedded in the core layer of a package. In some embodiments, the stacked circuit component devices may be part of a voltage regulation circuit for the package, and certain embodiments may even include both active and passive components of a voltage regulation circuit to be embedded within the core layer of a package substrate.

Aspects of the present disclosure may accordingly allow for the combination of both existing and emerging passive technologies, combining them into one device that can be embedded in an integrated circuit package. The device can provide inductance and capacitance at higher densities than previous solutions that embed such components individually. In addition, aspects of the present disclosure may enable custom embedded circuit solutions, enabling higher performance applications. In addition, the modular structure of embodiments herein allows them to be combined with active devices, e.g., high voltage GaN power field-effect transistors (FETs) to provide a standalone voltage regulator circuit that can be embedded.

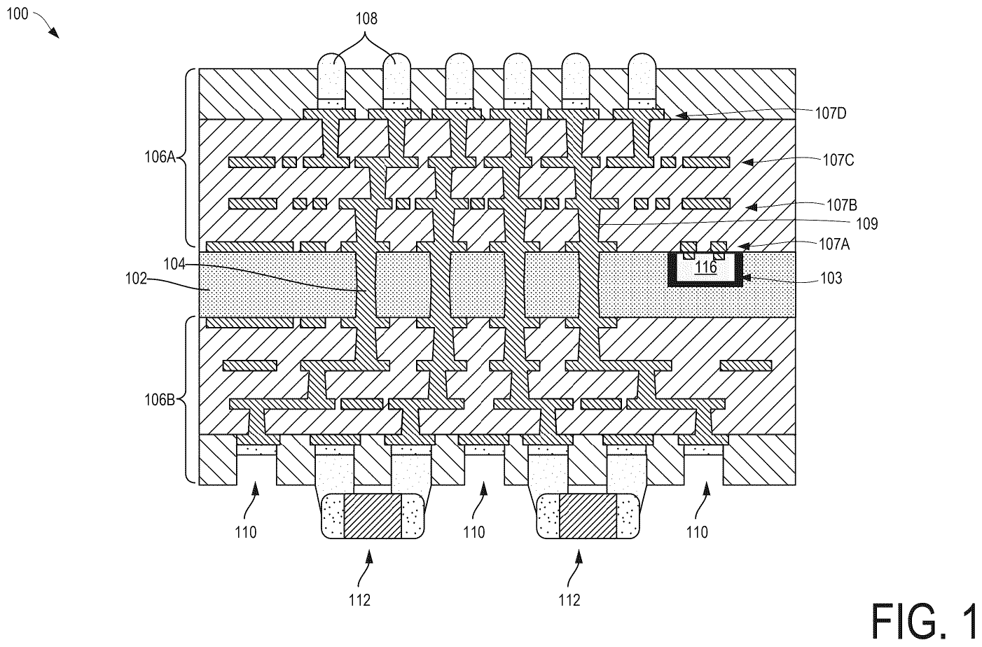

FIG. 1 illustrates an example package substrate 100 with an embedded component in a core layer. In particular, the example package substrate 100 includes a core layer 102 with buildup layers 106 formed on either side of the core layer 102, i.e., with buildup layers 106A on the top side of the core layer 102 and buildup layers 106B on the bottom side of the core layer 102. The buildup layers 106 include metal traces in metallization layers (e.g., 107A-D) and vias (e.g., 109) between the metallization layers to electrically couple the solder bumps 108 at the top of the package substrate 100 with the pads 110 at the bottom of the substrate. In certain instances, for example, an integrated circuit die may be coupled to a top side of the package substrate 100 and connect to the solder bumps 108, and the package substrate 100 may be coupled to a circuit board (e.g., a motherboard, main board, etc.) via the pads 110 at the bottom of the package substrate 100. The pads 110 may be referred to as “lands” for a land grid array (LGA). In other embodiments, the bottom side of the package substrate 100 may include solder balls (e.g., on the pads 110) for a ball grid array (BGA). The package substrate 100 also includes land side capacitors 112 coupled on a bottom side of the package substrate 100. The package substrate 100 further includes through core vias 104 (which may also be referred to as plated through holes (PTHs) in some cases) to electrically connect the metallization layers on either side of the core layer 102.

The package substrate 100 further includes a stacked circuit component device 116 that is embedded within the core layer 102, i.e., within a cavity 103 in the core layer 102. The device 116 may be a stacked circuit component device as described herein, and may be placed within a cavity (e.g., as shown) or hole in the core layer 102. The stacked circuit component device 116 may be encapsulated with a mold material inside the cavity/hole in the core layer 102.

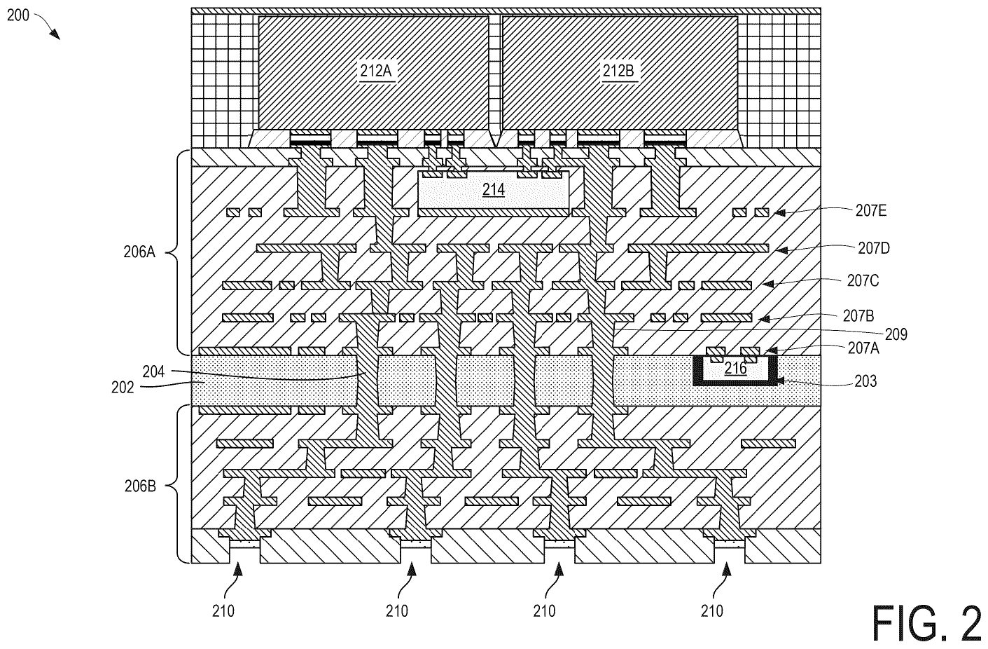

FIG. 2 illustrates an example multi-die integrated circuit package 200 with an embedded stacked circuit component device 216 in a core layer of the package substrate. The package 200 includes a core layer 202 and vias 204 through the core layer 202. Buildup layers 206 are formed on the top and bottom sides of the core layer 202, with buildup layers 206A on the top side of the core layer 202 and the buildup layers 206B on bottom side of the core layer 202. The buildup layers 206 include metal traces in metallization layers (e.g., 207A-E) and vias (e.g., 209) between the metallization layers as shown to electrically couple components on the top of the package 200 with the pads 210 at the bottom of the package. For example, the layers 206 may provide connections between the integrated circuit (IC) dies 212 coupled to the top side of the package to a circuit board (e.g., a motherboard, main board, etc.) via the pads 210 at the bottom of the package. The package 200 also includes through core vias 204 (which may also be referred to as plated through holes (PTHs) in some cases) to electrically connect the metallization layers on either side of the core layer 202.

The package 200 also includes a bridge circuitry component 214 located in the buildup layers 206A that electrically couples the first IC die 212A with the second IC die 212B. The bridge circuitry component 214 may include passive and/or active components to interconnect the IC dies 212. The bridge circuitry component 214 may be an Intel® embedded multi-die interconnect bridge (EMIB) in certain embodiments.

The package 200 further includes a stacked circuit component device 216 that is embedded within the core layer 202, i.e., within a cavity 203 in the core layer 202. Like the device 116 of FIG. 1, the device 216 may be stacked circuit component device as described herein, and may be placed within a cavity (e.g., as shown) or hole in the core layer 202. The device 216 may be encapsulated with a mold material inside the cavity/hole in the core layer 202.

In some embodiments, the core layers 102, 202 may comprise an organic material, e.g., a material comprising Carbon, such as comprising Silicon and Carbon. An example organic core layer material may be FR4, which is a silicon glass fiber woven epoxide matrix composite material. In other embodiments, the core layers 102, 202 may comprise glass or a glass-based material comprising Silicon (e.g., at least 23% by weight) and Oxygen (e.g., at least 26% by weight). A glass or glass-based core layer may amorphous and in some embodiments, may include one or more additive elements (e.g., as least 5% by weight) such as Aluminum, Boron, Magnesium, Calcium, Barium, Tin, Sodium, Potassium, Strontium, Phosphorus, Zirconium, Lithium, Titanium, and Zinc. Examples of glass core materials may include aluminosilicate, borosilicate, alumino-borosilicate, silica, or fused silica, and the materials may further include one or more additives, such as Al2O3, B2O3, MgO, CaO, SrO, BaO, SnO2, Na2O, K2O, SrO, P2O3, ZrO2, Li2O, Ti, and Zn. In some embodiments, the core layers 102, 202 may be made of a spin-on glass (SOG) material.

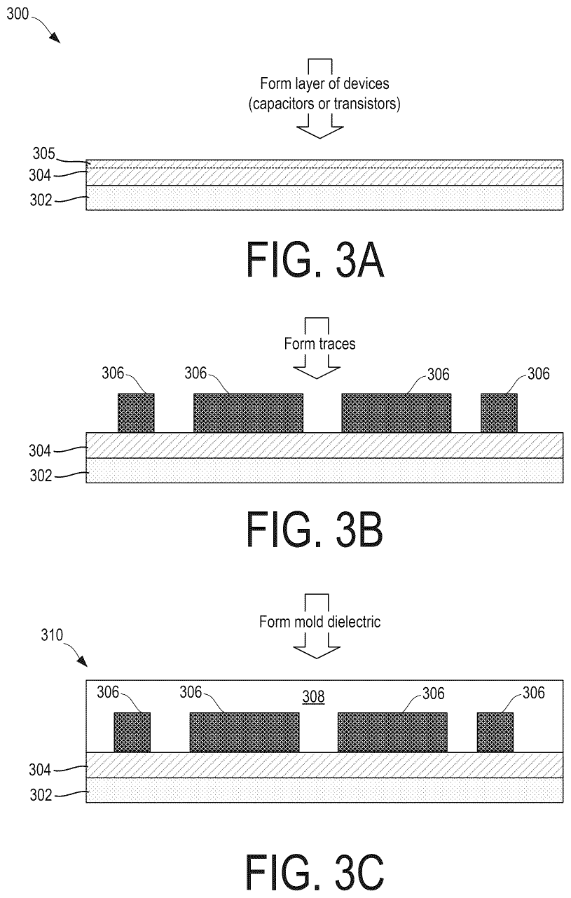

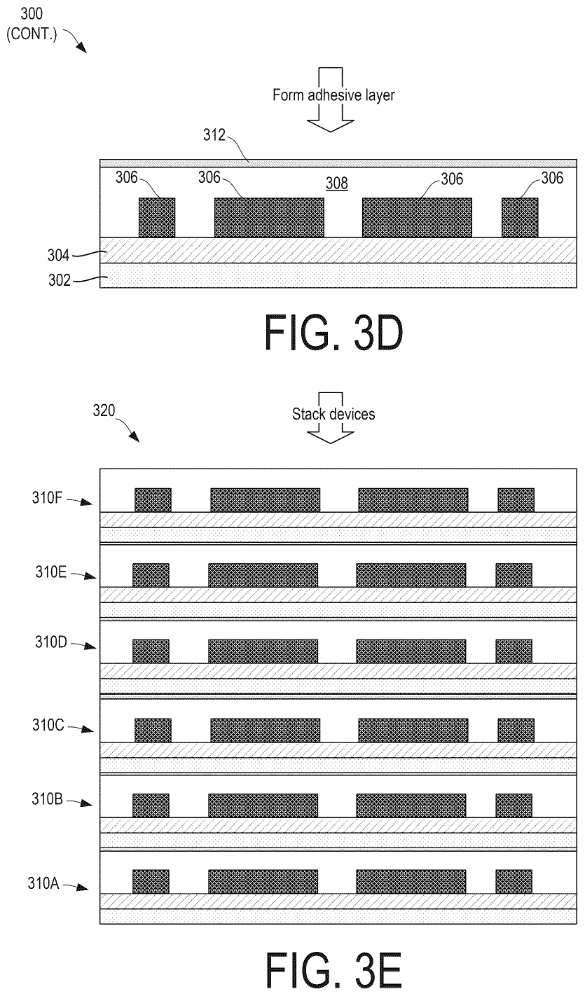

FIGS. 3A-3E illustrate an example process 300 of fabricating a circuit component assembly 310 that can be included in a stacked circuit component device 320. The example process 300 may be used, for example, to fabricate one or more assemblies of a stacked circuit component device that includes, for example, capacitors (e.g., deep trench capacitors (DTCs) or metal-in-metal (MIM) capacitors) or transistors. The process may include additional, fewer, or different operations than those shown or described below. Further, certain operations may be performed in a different order than shown or may be performed simultaneously (when shown as separate steps). In some embodiments, one or more of the operations shown include multiple operations, sub-operations, etc.

As shown in FIG. 3A, a stacked circuit component assembly can be fabricated by first forming a layer 304 comprising circuit components on a substrate 302. The substrate 302 may be any suitable material, e.g., a silicon or silicon-based substrate or a glass or glass-based substrate (e.g., a substrate comprising Silicon and Oxygen, such as SiO₂). The layer 304 may include passive and/or active circuit components. In some embodiments, the layer 304 includes capacitors, such as DTCs or MIMs, while in other embodiments, the layer 304 includes active components such as transistors. The layer 304 may also include one or more redistribution or interconnect layers (305) to connect the various capacitors or transistors of the layer 304 to conductive traces (e.g., 306) that are later formed on the layer 304.

Then, as shown in FIG. 3B, conductive traces 306 (e.g., metal) can be formed on the layer 304. The thickness of the traces 306 may be between 15 μm and 40 um (e.g., 25 um) in certain embodiments. The traces 306 can be created using a semi-additive process or by a thick metal deposition process, such as, for example, electroplating, electrospray, or cold spray. After the traces 306 are formed, a layer 308 of dielectric material (e.g. organic material) is formed around the traces 306 as shown in FIG. 3C. The layer 308 may include SiO₂, which can be slit- or spin-coated. The layer 308 may be also put through a grinding or polishing (e.g., chemical mechanical polishing (CMP)) process to be planarized. In some embodiments, before being placed into a stacked circuit component device, the substrate 302 of the assembly 310 may be thinned (e.g., to a minimum thickness that does not compromise capacitor/transistor performance or reliability). As an example, where DTCs are included in the layer 304, the total thickness of the resulting component assembly 310 may be between 50-250 um.

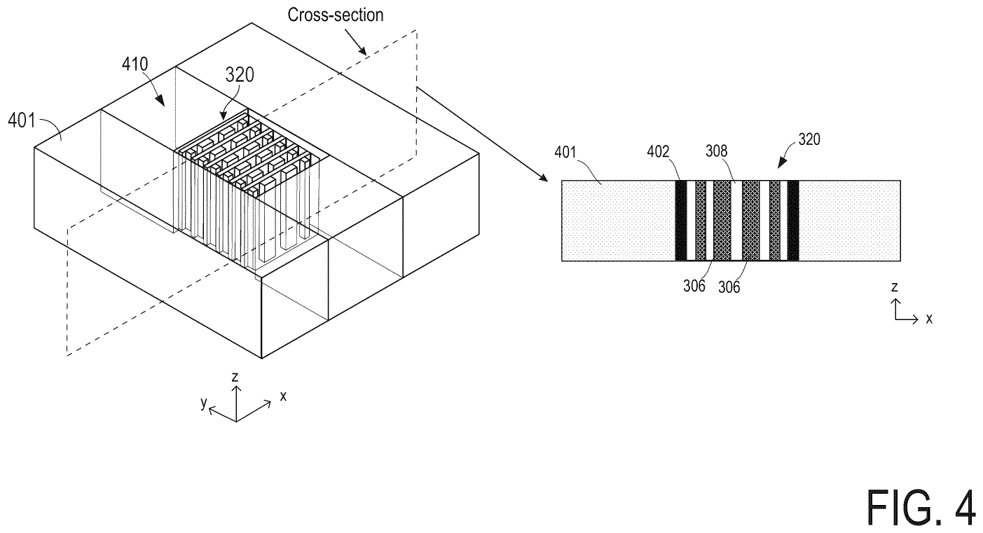

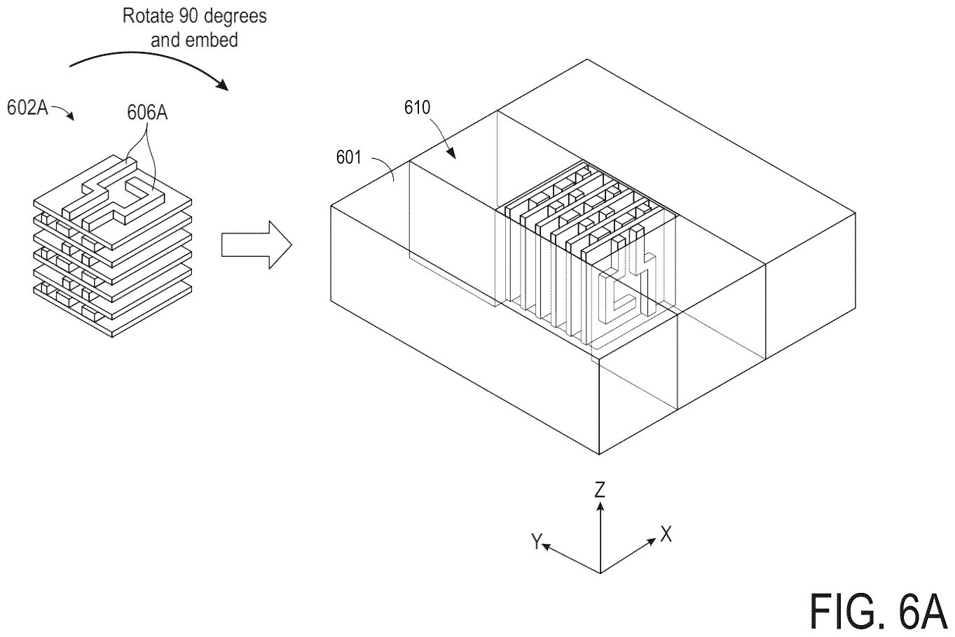

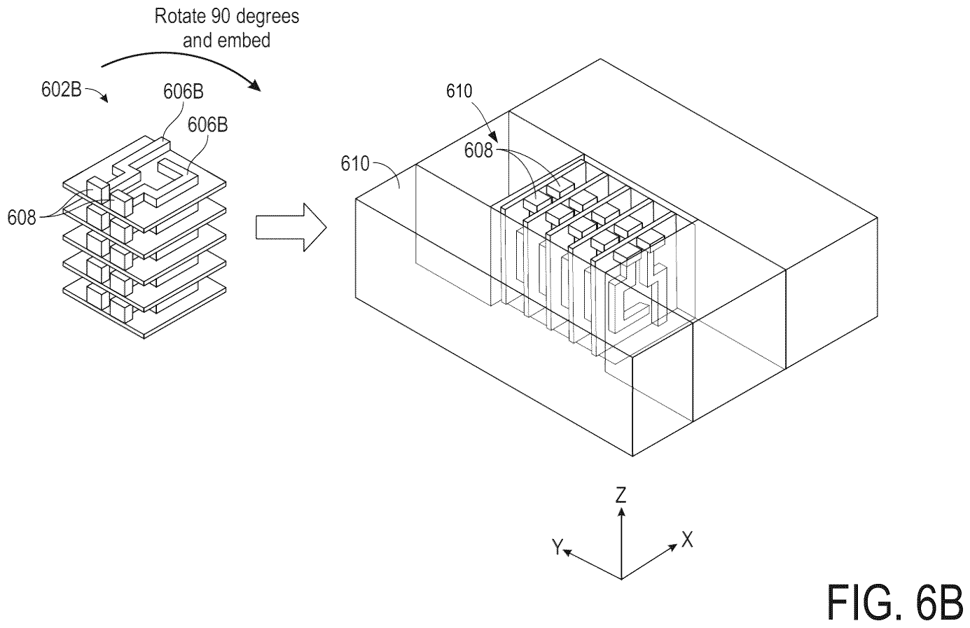

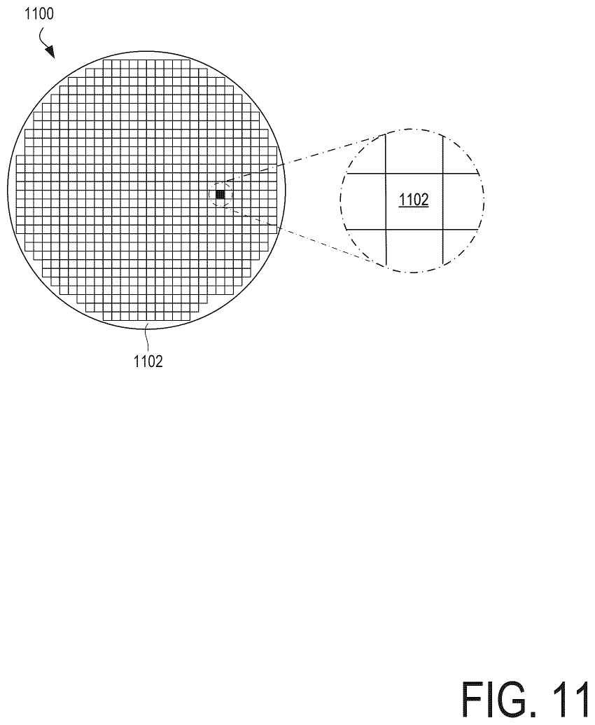

The resulting component assembly 310 can then be placed in a stacked circuit component device. For example, as shown in FIG. 3D, an adhesive layer 312 (e.g., a layer of tape or bond material) is applied on the surface of the dielectric layer 308 as shown, and then the component assembly 310 can be placed into a stacked component device, such as the device 320 shown in FIG. 3E which includes a number of component assemblies 310 (e.g., 310A-310F) stacked on one another. In the examples shown, each assembly 310 is manufactured such that it is generally planar, and when stacked in the device 320, each assembly becomes substantially parallel with one another. In some use cases, each component assembly 310 may be a die of a wafer (e.g., as shown in FIG. 11) that is stacked and diced to create a desired stacked component structure (e.g., one similar to the device 320 shown in FIG. 3E). The stacked circuit component device 320 can then be rotated (e.g., approximately 90°) and embedded into a core layer of a package substrate, e.g., as shown in FIG. 4 (and also in FIGS. 6A-6B). In this way, the planes of the stacked devices are then orthogonal or substantially orthogonal or to the general plane of the core layer of the package substrate.

Capacitance densities of DTCs may be approximately 1.5 uF/mm² currently, with future projections extending this value upwards to approximately 2-2.5 uF/mm². Accordingly, stacking four assemblies 310 could allow for a capacitance density of up to 6 uF/mm² within a single device 320, a density that cannot be reached presently by any monolithic technology. Since the assemblies are interconnected to each other through the substrate package interconnects and not through TSVs, this helps to further maximize density and importantly, can maximize design flexibility as now the package and product designer can decide on how to implement the passive components for embedding in the core layer. For instance, in the example above with four capacitor assemblies 310, one might want to keep the capacitance constant while doubling the supply voltage. In that case, through package substrate interconnects, a pair of the capacitor assemblies can be connected in series and those pairs then be connected in parallel to yield a density of 1.5 uF/mm², however the supply voltage could be doubled from, for example, 1.8V or 2.3V to 3.6V or 4.6V.

FIG. 4 illustrates the stacked circuit component device 320 produced by the process 300 of FIG. 3 embedded in a core layer 401 of an integrated circuit package substrate. In particular, FIG. 4 illustrates how the stacked circuit component device 320 (or other stacked components described herein) may be rotated before embedding into an opening 410 within the core layer 401 such that the ends of the traces 306 (which are shown going into/out of the page in FIGS. 3A-3E and running vertically in the right side of FIG. 4) may be accessible at the top and/or bottom of the core layer 401 (in the z-direction shown). In this way, each of the various component assemblies 310 of the stacked component device 320 can be accessed by buildup layers above and/or below the core layer 401.

Put another way, in the example shown, the device 320 is oriented within the core layer 401 such that the plane of each assembly 310 in the device 320 is substantially parallel with one another and each is also substantially orthogonal to the plane of the core layer 401. For instance, in the example shown, the traces 306 of the device 320 are oriented in the x-z plane as shown on the right side of FIG. 4, while the core layer 401 is oriented in the x-y plane. That is, the planes of the traces 306 of the assemblies and/or planes in which the circuit components are located in the assemblies, such as the plane of the layer 304 shown in FIGS. 3A-3E, is at least substantially orthogonal to the plane of the core layer. As used herein, substantially orthogonal may refer to an orientation where one item (e.g., the plane of the layer 304 or the plane in which the traces 306 are located) is oriented within 10 degrees of orthogonal to (e.g., at an angle between 85-95 degrees with respect to) another item (e.g., the core layer 401). Similarly, substantially parallel may refer to an orientation where one item (e.g., the plane of a first assembly 310 of the device 320) is oriented within 10 degrees of parallel to (e.g., at an angle between −5-5 degrees with respect to) another item (e.g., the plane of a second assembly 310 of the device 320). Although the particular device 320 is shown in FIG. 4, other embodiments of the present disclosure may include other stacked circuit component devices in accordance with the present disclosure, such as those shown in other FIGS. and described further below.

The core layer 401 may comprise an organic material (e.g., a material comprising Carbon, such as comprising Silicon and Carbon), while in other embodiments, the core layers 102, 202 may comprise glass or a glass-based material comprising Silicon (e.g., at least 23% by weight) and Oxygen (e.g., at least 26% by weight). A glass or glass-based core layer may amorphous and in some embodiments, may include one or more additive elements (e.g., as least 5% by weight) such as Aluminum, Boron, Magnesium, Calcium, Barium, Tin, Sodium, Potassium, Strontium, Phosphorus, Zirconium, Lithium, Titanium, and Zinc. Examples of glass core materials may include aluminosilicate, borosilicate, alumino-borosilicate, silica, or fused silica, and the materials may further include one or more additives, such as Al2O3, B2O3, MgO, CaO, SrO, BaO, SnO2, Na2O, K₂O, SrO, P2O3, ZrO2, Li2O, Ti, and Zn. In some embodiments, the core layers 102, 202 may be made of a spin-on glass (SOG) material.

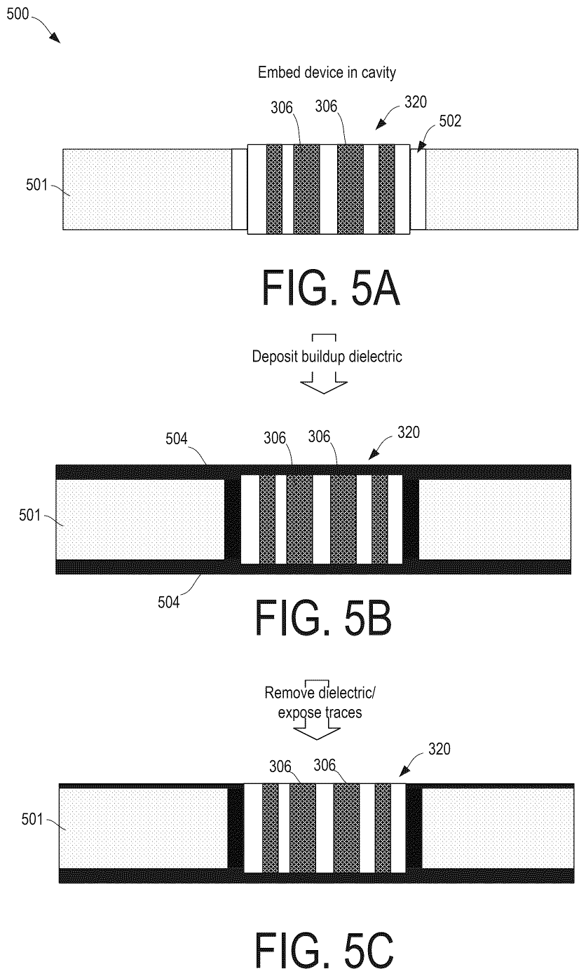

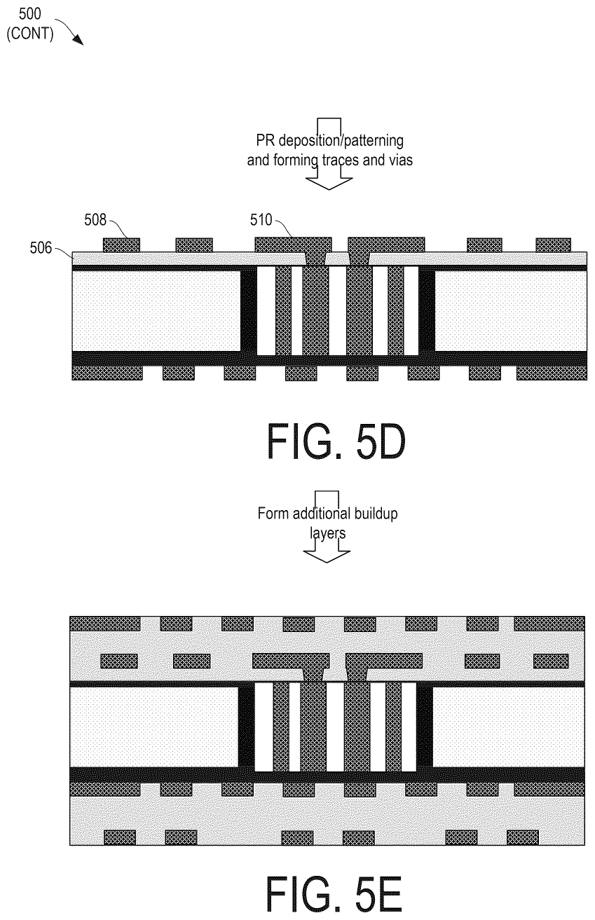

FIGS. 5A-5D illustrate an example process 500 of fabricating buildup layers on the core layer 401 in FIG. 4. The process may include additional, fewer, or different operations than those shown or described below. Further, certain operations may be performed in a different order than shown or may be performed simultaneously (when shown as separate steps). In some embodiments, one or more of the operations shown include multiple operations, sub-operations, etc.

As shown in FIG. 5A, the stacked circuit component device 320 is embedded within a cavity or opening 502 within the core layer 501 as shown. The device 320 may be oriented in the same or similar manner as shown in FIG. 4, that is, with the plane of the conductive traces 306 of the device 320 (which are vertical in the FIGS. 5A-5D) being orthogonal or substantially orthogonal to the plane of the core layer 501. In some embodiments, a dimension of the device 320 in the vertical direction shown in FIG. 5A (which is into/out of the page for the device 320 as it is shown in FIGS. 3A-3E), may be approximately equal to the height of the core layer 501, while in some embodiments, the same dimension may be greater than the height of the core layer 501. The size of this dimension of the device 320 may be a design parameter that, in some cases, may depend on the space made available in the substrate core or the capacitance or inductance values required by the device 320.

Once the device 320 is embedded into the core layer 501, a buildup dielectric 504 can be deposited as shown in FIG. 5B to encapsulate the device 320 within the core layer 501. The dielectric 504 may also cover the top and bottom portions of the core layer 501 and the device 320 as shown. The layer of dielectric 504 can then be removed, e.g., via a grinding or polishing process, to expose the traces 306 of the device 320. Although shown as being performed only on the top side of the assembly in FIG. 5C, the dielectric 504 may be removed from both sides of the core layer to expose both sides of the device 320. Then, as shown in FIG. 5D, a photo-patternable or photoimageable dielectric layer 506 can be deposited, patterned, and etched for the deposition of conductive traces 508 and 510 (which include vias connected to the traces 306 of the device 320). In other embodiments, the layer 506 may be a non-photo-patternable or non-photoimageable buildup dielectric layer, and the vias can be patterned, e.g., by laser drilling and a seed layer being deposited in the openings. The traces 508 can then be deposited, e.g., by electroplating, after typical photolithography process with photoresist materials, and the photo resist can be removed and the seed layer etched. Thereafter, additional buildup layers on both sides of the assembly as shown in FIG. 5E, e.g., using the same process(es) described above.

In the previous examples, the traces 306 of the device 320 were formed in straight lines across the device (e.g., as shown in FIG. 4). However, some embodiments may implement the traces 306 in different formations, e.g., with the traces 306 being non-straight, curved, etc. as needed or desired. Further, the traces 306 of the different component assemblies 310 of the same device may have traces 306 with the same or different formations as one another. Moreover, although shown as having traces 306 with uniform thickness, the traces 306 may be formed with variable thicknesses in certain embodiments.

FIGS. 6A-6B illustrate example embodiments of stacked circuit component devices 602 with traces 606 having different formations embedded within an opening 610 in a core layer 601 of an integrated circuit package substrate. In the examples shown, the traces 606 may function similar to the traces 306 described above, but are formed such that they are not straight across the device, e.g., as shown in FIG. 4. In particular, the traces 606A, 606B are formed with various turns in their routing, which may be beneficial for certain types of component assemblies. Referring specifically to the example shown in FIG. 6B, the traces 606B include respective pad areas 608 that are slightly larger in dimension (e.g., larger in area in the x-y plane) than the other portions of the traces further down in the z-direction. The pad areas 608 could be, for example, between 1-50 um thick (in the z-direction of the core layer 601) and slightly larger in dimension than the traces 606 (e.g., between 25 um-80 wide in the x-y dimensions). This structure can also be used in inductor component assemblies to enable better connectivity to rest of the package substrate, and may also be used in active circuitry component assemblies, e.g., in the use case of an active VR device embedded within the core layer.

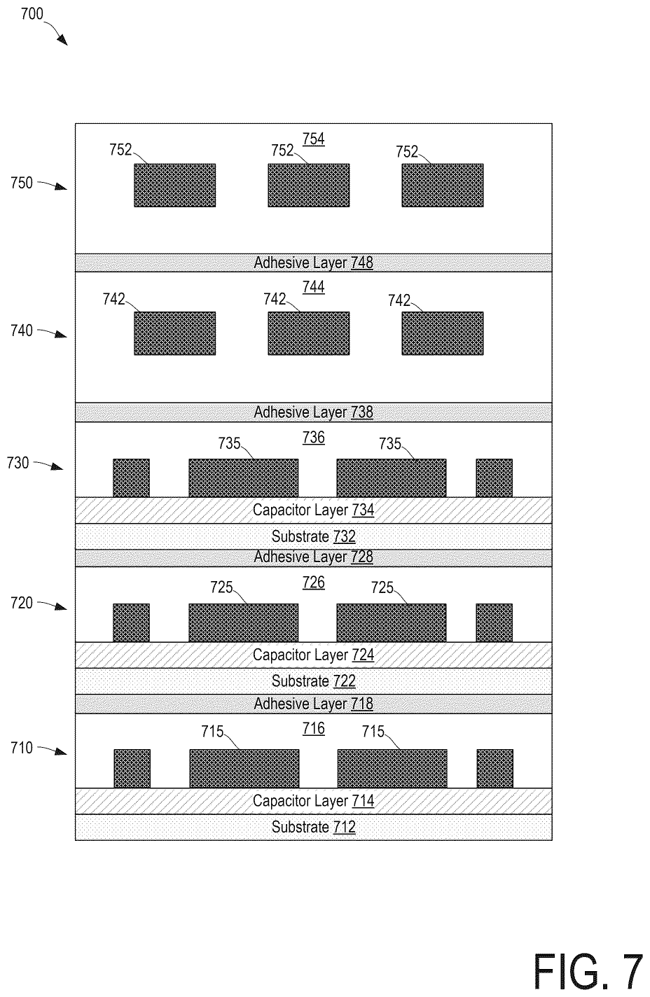

FIG. 7 illustrates an example stacked circuit component device 700 in accordance with embodiments of the present disclosure. In particular, the device 700 includes component assemblies 710, 720, 730, 740, and 750, where the assemblies 710, 720, and 730 are capacitor assemblies and the assemblies 740 and 750 are inductor assemblies. The assemblies are coupled together using adhesive layers 718, 728, 738, 748. Each capacitor assembly includes a substrate (712, 722, 732) with a layer comprising capacitors (714, 724, 734) thereon. The capacitors may include DTCs in certain embodiments, or other types of capacitors. The capacitor assemblies also include conductive traces (715, 725, 735) formed on the layer of capacitors, which are encapsulated in a dielectric material (716, 726, 736), similar to the previously described assemblies. The inductor assemblies are similar to magnetic inductor arrays (MIAs), and include traces (742, 752) within a magnetic material (744, 754). The thickness of the inductor assemblies (in the vertical direction of FIG. 7) may be between 50 μm and 1 mm in certain embodiments.

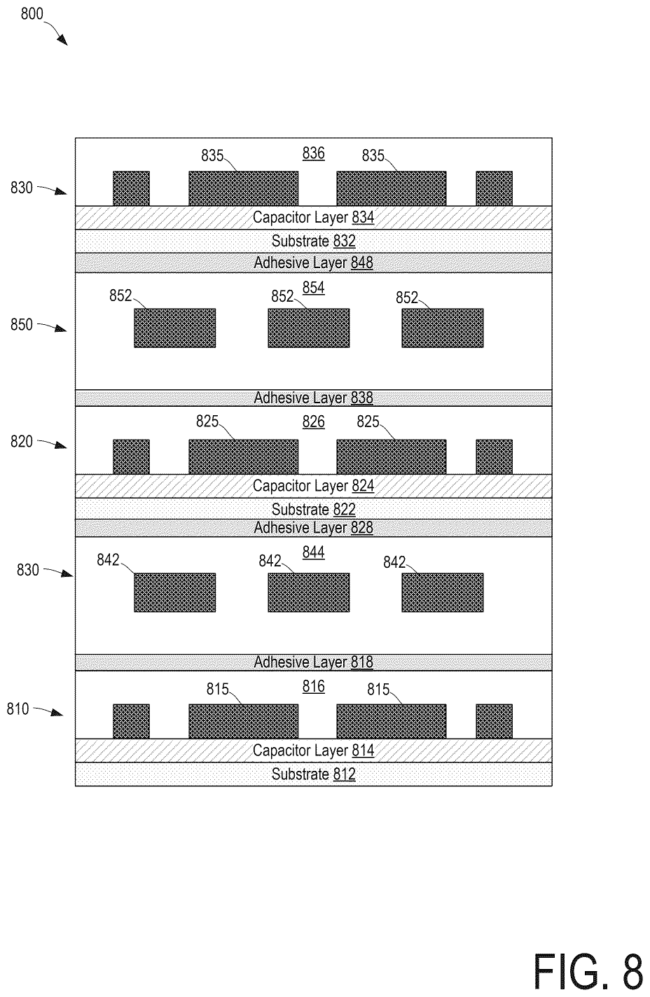

FIG. 8 illustrates another example stacked circuit component device 800 in accordance with embodiments of the present disclosure. In particular, the device 800 includes the same number and type of component assemblies as in FIG. 7, but with the capacitor and inductor assemblies being interleaved with one another instead of grouped together by type.

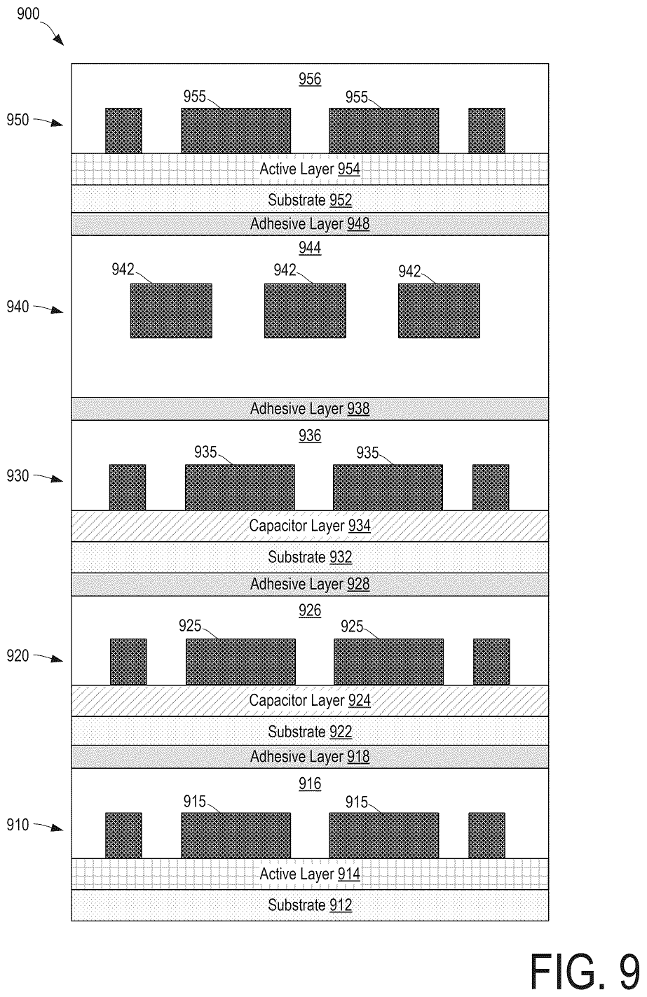

FIG. 9 illustrates yet another example stacked circuit component device 900 in accordance with embodiments of the present disclosure. In particular, the device 900 includes active component assemblies 910, 950 in addition to capacitor assemblies 920, 930 and an inductor assembly 940. The assemblies 910, 950 is formed similar to the capacitor assemblies described previously, each with an active layer (914, 954) comprising transistors formed on a substrate (912, 952), and conductive contacts (915, 955) formed on the active layer (914, 954) and encapsulated in dielectric (916, 956). As with the other examples, the conductive contacts can connect the transistors of the active layers to the metallization layers of the package substrate. Each capacitor assembly 920, 930 is formed similar to the capacitor assemblies above, with capacitor layers 924, 934 formed on substrates 922, 932, and conductive contacts 925, 925 (encapsulated in dielectrics 926, 936) formed on the capacitors layers to interconnect the capacitors to the package substrate layers. The inductor assembly 940 includes conductive traces 942 formed within a magnetic material 944.

The example device 900 may be a stand-alone voltage regulator (VR) device solution for power conversion and supplying power to a die coupled to the package substrate (e.g., to a die coupled to the solder bumps 108 of FIG. 1 or the dies 212 of FIG. 2). The proposed VR device can include different numbers of active, capacitor, or inductor assemblies than those shown in FIG. 9, and such assemblies can be arranged in a different manner than shown. For example, there may be multiple active device assemblies where more or larger switching transistors are required. One advantage of a contained VR device such as the one shown is that it can offload active switching devices from the dies of the package, so that such area can be dedicated to computation, communication, etc. In addition, it can allow for a low-cost solution to heterogeneous integration in that the switching devices can be of any suitable semiconductor material and using any technology, so they don't have to be compatible with Silicon complementary metal-oxide semiconductor (CMOS) processing. For instance, low cost can be achieved since no solution such as through-silicon vias (TSVs) or hybrid bonding interconnect (HBI) is required to integrate the active devices into the package since everything is integrated through the package interconnect layers.

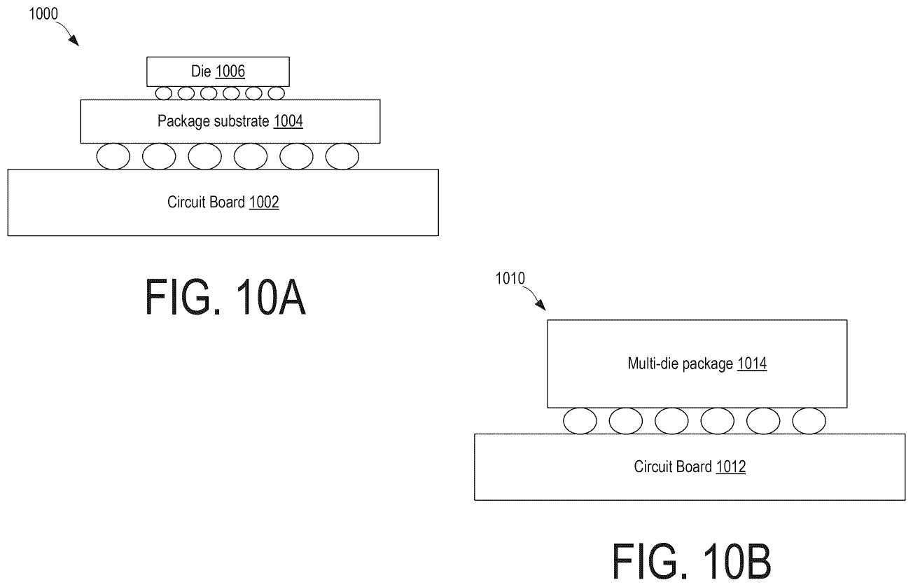

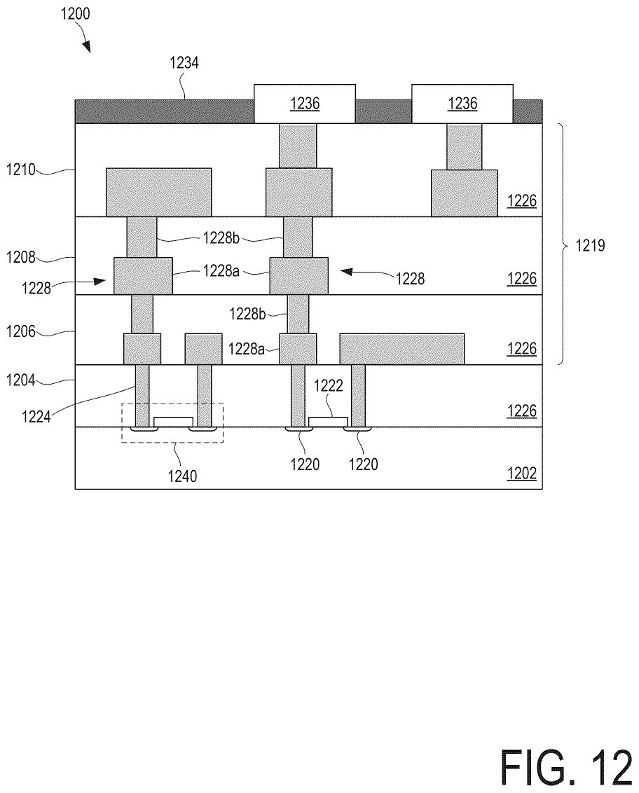

FIGS. 10A-10B illustrate example systems 1000, 1010 that may incorporate the architectures described herein. The example system 1000 of FIG. 10A includes a circuit board 1002, which may be implemented as a motherboard or main board of a computer system in some embodiments. The example system 1000 also includes a package substrate 1004 with an integrated circuit die 1006 attached to the package substrate 1004. The die 1006 may be a packaged or unpacked integrated circuit product that includes one or more integrated circuit dies (e.g., the die 1102 of FIG. 11, the integrated circuit device 1200 of FIG. 12) and/or one or more other suitable components. The die 1006 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the die 1006 can comprise one or more additional active or passive devices such as capacitors, decoupling capacitors, resistors, inductors, fuses, diodes, transformers, sensors, electrostatic discharge (ESD) devices, and memory devices. In addition to comprising one or more processor units, the die 1006 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. The package substrate 1004 may provide electrical connections between the die 1006 and the circuit board 1002.

Similar to the system 1000, the system 1010 also includes a circuit board 1012, which may be implemented as a motherboard or main board of a computer system in some embodiments. The system 1010 also includes a multi-die package 1014, which includes multiple integrated circuits/dies (e.g., 1006), and interconnections between the dies in one or more metallization layers. The multi-die package 1014 may include, for example, one or more silicon interposers, one or more silicon bridges embedded in the package substrate (e.g., an Intel® embedded multi-die interconnect bridge (EMIB)), or combinations thereof.

The main circuit boards 1002, 1012 may provide electrical connections to other components of a computer system, e.g., memory, storage, network interfaces, peripheral devices, power supplies, etc. The main circuit board may include one or more traces and circuit components to provide interconnects between such computer system components.

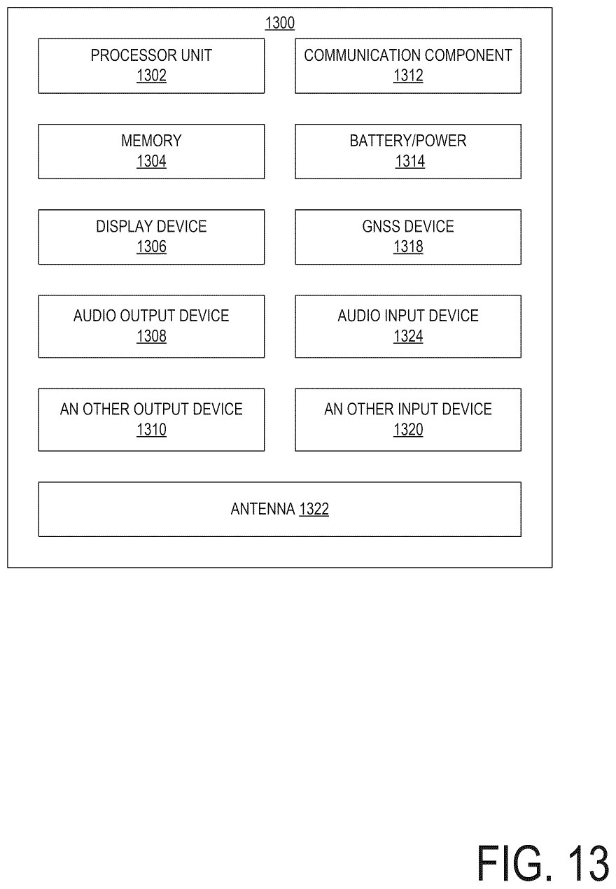

FIG. 11 is a top view of a wafer 1100 and dies 1102 that may incorporate any of the embodiments disclosed herein. The wafer 1100 may be composed of semiconductor material and may include one or more dies 1102 having integrated circuit structures formed on a surface of the wafer 1100. The individual dies 1102 may be a repeating unit of an integrated circuit product that includes any suitable integrated circuit. After the fabrication of the semiconductor product is complete, the wafer 1100 may undergo a singulation process in which the dies 1102 are separated from one another to provide discrete “chips” of the integrated circuit product. The die 1102 may include one or more transistors (e.g., some of the transistors 1240 of FIG. 12, discussed below), supporting circuitry to route electrical signals to the transistors, passive components (e.g., signal traces, resistors, capacitors, or inductors), and/or any other integrated circuit components. In some embodiments, the wafer 1100 or the die 1102 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1102. For example, a memory array formed by multiple memory devices may be formed on a same die 1102 as a processor unit (e.g., the processor unit 1302 of FIG. 13) or other logic that is configured to store information in the memory devices or execute instructions stored in the memory array.

FIG. 12 is a cross-sectional side view of an integrated circuit device 1200 that may be included in any of the embodiments disclosed herein. One or more of the integrated circuit devices 1200 may be included in one or more dies 1102 (FIG. 11). The integrated circuit device 1200 may be formed on a die substrate 1202 (e.g., the wafer 1100 of FIG. 11) and may be included in a die (e.g., the die 1102 of FIG. 11). The die substrate 1202 may be a semiconductor substrate composed of semiconductor material systems including, for example, n-type or p-type materials systems (or a combination of both). The die substrate 1202 may include, for example, a crystalline substrate formed using a bulk silicon or a silicon-on-insulator (SOI) substructure. In some embodiments, the die substrate 1202 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1202. Although a few examples of materials from which the die substrate 1202 may be formed are described here, any material that may serve as a foundation for an integrated circuit device 1200 may be used. The die substrate 1202 may be part of a singulated die (e.g., the dies 1102 of FIG. 11) or a wafer (e.g., the wafer 1100 of FIG. 11).

The integrated circuit device 1200 may include one or more device layers 1204 disposed on the die substrate 1202. The device layer 1204 may include features of one or more transistors 1240 (e.g., metal oxide semiconductor field-effect transistors (MOSFETs) or ferroelectric field-effect transistors (FeFETs), e.g., those described herein) formed on the die substrate 1202. The transistors 1240 may include, for example, one or more source and/or drain (S/D) regions 1220, a gate 1222 to control current flow between the S/D regions 1220, and one or more S/D contacts 1224 to route electrical signals to/from the S/D regions 1220. The transistors 1240 may include additional features not depicted for the sake of clarity, such as device isolation regions, gate contacts, and the like. The transistors 1240 are not limited to the type and configuration depicted in FIG. 12 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 12, the example transistor 1240 may include a gate 1222 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1240 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1240 along the source-channel-drain direction, the gate electrode may consist of a U-shaped structure that includes a bottom portion substantially parallel to the surface of the die substrate 1202 and two sidewall portions that are substantially perpendicular to the top surface of the die substrate 1202. In other embodiments, at least one of the metal layers that form the gate electrode may simply be a planar layer that is substantially parallel to the top surface of the die substrate 1202 and does not include sidewall portions substantially perpendicular to the top surface of the die substrate 1202. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1220 may be formed within the die substrate 1202 adjacent to the gate 1222 of individual transistors 1240. The S/D regions 1220 may be formed using an implantation/diffusion process or an etching/deposition process, for example. In the former process, dopants such as boron, aluminum, antimony, phosphorous, or arsenic may be ion-implanted into the die substrate 1202 to form the S/D regions 1220. An annealing process that activates the dopants and causes them to diffuse farther into the die substrate 1202 may follow the ion-implantation process. In the latter process, the die substrate 1202 may first be etched to form recesses at the locations of the S/D regions 1220. An epitaxial deposition process may then be carried out to fill the recesses with material that is used to fabricate the S/D regions 1220. In some implementations, the S/D regions 1220 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1220 may be formed using one or more alternate semiconductor materials such as germanium or a group III-V material or alloy. In further embodiments, one or more layers of metal and/or metal alloys may be used to form the S/D regions 1220.

Electrical signals, such as power and/or input/output (I/O) signals, may be routed to and/or from the devices (e.g., transistors 1240) of the device layer 1204 through one or more interconnect layers disposed on the device layer 1204 (illustrated in FIG. 12 as interconnect layers 1206-1210). For example, electrically conductive features of the device layer 1204 (e.g., the gate 1222 and the S/D contacts 1224) may be electrically coupled with the interconnect structures 1228 of the interconnect layers 1206-1210. The one or more interconnect layers 1206-1210 may form a metallization stack (also referred to as an “ILD stack”) 1219 of the integrated circuit device 1200.

The interconnect structures 1228 may be arranged within the interconnect layers 1206-1210 to route electrical signals according to a wide variety of designs; in particular, the arrangement is not limited to the particular configuration of interconnect structures 1228 depicted in FIG. 12. Although a particular number of interconnect layers 1206-1210 is depicted in FIG. 12, embodiments of the present disclosure include integrated circuit devices having more or fewer interconnect layers than depicted.

In some embodiments, the interconnect structures 1228 may include lines 1228a and/or vias 1228b filled with an electrically conductive material such as a metal. The lines 1228a may be arranged to route electrical signals in a direction of a plane that is substantially parallel with a surface of the die substrate 1202 upon which the device layer 1204 is formed. For example, the lines 1228a may route electrical signals in a direction in and out of the page and/or in a direction across the page from the perspective of FIG. 12. The vias 1228b may be arranged to route electrical signals in a direction of a plane that is substantially perpendicular to the surface of the die substrate 1202 upon which the device layer 1204 is formed. In some embodiments, the vias 1228b may electrically couple lines 1228a of different interconnect layers 1206-1210 together.

The interconnect layers 1206-1210 may include a dielectric material 1226 disposed between the interconnect structures 1228, as shown in FIG. 12. In some embodiments, dielectric material 1226 disposed between the interconnect structures 1228 in different ones of the interconnect layers 1206-1210 may have different compositions; in other embodiments, the composition of the dielectric material 1226 between different interconnect layers 1206-1210 may be the same. The device layer 1204 may include a dielectric material 1226 disposed between the transistors 1240 and a bottom layer of the metallization stack as well. The dielectric material 1226 included in the device layer 1204 may have a different composition than the dielectric material 1226 included in the interconnect layers 1206-1210; in other embodiments, the composition of the dielectric material 1226 in the device layer 1204 may be the same as a dielectric material 1226 included in any one of the interconnect layers 1206-1210.

A first interconnect layer 1206 (referred to as Metal 1 or “M1”) may be formed directly on the device layer 1204. In some embodiments, the first interconnect layer 1206 may include lines 1228a and/or vias 1228b, as shown. The lines 1228a of the first interconnect layer 1206 may be coupled with contacts (e.g., the S/D contacts 1224) of the device layer 1204. The vias 1228b of the first interconnect layer 1206 may be coupled with the lines 1228a of a second interconnect layer 1208.

The second interconnect layer 1208 (referred to as Metal 2 or “M2”) may be formed directly on the first interconnect layer 1206. In some embodiments, the second interconnect layer 1208 may include via 1228b to couple the lines 1228 of the second interconnect layer 1208 with the lines 1228a of a third interconnect layer 1210. Although the lines 1228a and the vias 1228b are structurally delineated with a line within individual interconnect layers for the sake of clarity, the lines 1228a and the vias 1228b may be structurally and/or materially contiguous (e.g., simultaneously filled during a dual-damascene process) in some embodiments.

The third interconnect layer 1210 (referred to as Metal 3 or “M3”) (and additional interconnect layers, as desired) may be formed in succession on the second interconnect layer 1208 according to similar techniques and configurations described in connection with the second interconnect layer 1208 or the first interconnect layer 1206. In some embodiments, the interconnect layers that are “higher up” in the metallization stack 1219 in the integrated circuit device 1200 (i.e., farther away from the device layer 1204) may be thicker that the interconnect layers that are lower in the metallization stack 1219, with lines 1228a and vias 1228b in the higher interconnect layers being thicker than those in the lower interconnect layers.

The integrated circuit device 1200 may include a solder resist material 1234 (e.g., polyimide or similar material) and one or more conductive contacts 1236 formed on the interconnect layers 1206-1210. In FIG. 12, the conductive contacts 1236 are illustrated as taking the form of bond pads. The conductive contacts 1236 may be electrically coupled with the interconnect structures 1228 and configured to route the electrical signals of the transistor(s) 1240 to external devices. For example, solder bonds may be formed on the one or more conductive contacts 1236 to mechanically and/or electrically couple an integrated circuit die including the integrated circuit device 1200 with another component (e.g., a printed circuit board). The integrated circuit device 1200 may include additional or alternate structures to route the electrical signals from the interconnect layers 1206-1210; for example, the conductive contacts 1236 may include other analogous features (e.g., posts) that route the electrical signals to external components.

In some embodiments in which the integrated circuit device 1200 is a double-sided die, the integrated circuit device 1200 may include another metallization stack (not shown) on the opposite side of the device layer(s) 1204. This metallization stack may include multiple interconnect layers as discussed above with reference to the interconnect layers 1206-1210, to provide conductive pathways (e.g., including conductive lines and vias) between the device layer(s) 1204 and additional conductive contacts (not shown) on the opposite side of the integrated circuit device 1200 from the conductive contacts 1236.

In other embodiments in which the integrated circuit device 1200 is a double-sided die, the integrated circuit device 1200 may include one or more through silicon vias (TSVs) through the die substrate 1202; these TSVs may make contact with the device layer(s) 1204, and may provide conductive pathways between the device layer(s) 1204 and additional conductive contacts (not shown) on the opposite side of the integrated circuit device 1200 from the conductive contacts 1236. In some embodiments, TSVs extending through the substrate can be used for routing power and ground signals from conductive contacts on the opposite side of the integrated circuit device 1200 from the conductive contacts 1236 to the transistors 1240 and any other components integrated into the die 1200, and the metallization stack 1219 can be used to route I/O signals from the conductive contacts 1236 to transistors 1240 and any other components integrated into the die 1200.

Multiple integrated circuit devices 1200 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 13 is a block diagram of an example electrical device 1300 that may include one or more of the embodiments disclosed herein. For example, any suitable ones of the components of the electrical device 1300 may include one or more of the integrated circuit devices 1200 or integrated circuit dies 1102 disclosed herein. A number of components are illustrated in FIG. 13 as included in the electrical device 1300, but any one or more of these components may be omitted or duplicated, as suitable for the application. In some embodiments, some or all of the components included in the electrical device 1300 may be attached to one or more motherboards mainboards, or system boards. In some embodiments, one or more of these components are fabricated onto a single system-on-a-chip (SoC) die.

Additionally, in various embodiments, the electrical device 1300 may not include one or more of the components illustrated in FIG. 13, but the electrical device 1300 may include interface circuitry for coupling to the one or more components. For example, the electrical device 1300 may not include a display device 1306, but may include display device interface circuitry (e.g., a connector and driver circuitry) to which a display device 1306 may be coupled. In another set of examples, the electrical device 1300 may not include an audio input device 1324 or an audio output device 1308, but may include audio input or output device interface circuitry (e.g., connectors and supporting circuitry) to which an audio input device 1324 or audio output device 1308 may be coupled.

The electrical device 1300 may include one or more processor units 1302 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1302 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1300 may include a memory 1304, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1304 may include memory that is located on the same integrated circuit die as the processor unit 1302. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1300 can comprise one or more processor units 1302 that are heterogeneous or asymmetric to another processor unit 1302 in the electrical device 1300. There can be a variety of differences between the processing units 1302 in a system in terms of a spectrum of metrics of merit including architectural, microarchitectural, thermal, power consumption characteristics, and the like. These differences can effectively manifest themselves as asymmetry and heterogeneity among the processor units 1302 in the electrical device 1300.

In some embodiments, the electrical device 1300 may include a communication component 1312 (e.g., one or more communication components). For example, the communication component 1312 can manage wireless communications for the transfer of data to and from the electrical device 1300. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1312 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1312 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1312 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1312 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1312 may operate in accordance with other wireless protocols in other embodiments. The electrical device 1300 may include an antenna 1322 to facilitate wireless communications and/or to receive other wireless communications (such as AM or FM radio transmissions).

In some embodiments, the communication component 1312 may manage wired communications, such as electrical, optical, or any other suitable communication protocols (e.g., IEEE 802.3 Ethernet standards). As noted above, the communication component 1312 may include multiple communication components. For instance, a first communication component 1312 may be dedicated to shorter-range wireless communications such as Wi-Fi or Bluetooth, and a second communication component 1312 may be dedicated to longer-range wireless communications such as global positioning system (GPS), EDGE, GPRS, CDMA, WiMAX, LTE, EV-DO, or others. In some embodiments, a first communication component 1312 may be dedicated to wireless communications, and a second communication component 1312 may be dedicated to wired communications.

The electrical device 1300 may include battery/power circuitry 1314. The battery/power circuitry 1314 may include one or more energy storage devices (e.g., batteries or capacitors) and/or circuitry for coupling components of the electrical device 1300 to an energy source separate from the electrical device 1300 (e.g., AC line power).

The electrical device 1300 may include a display device 1306 (or corresponding interface circuitry, as discussed above). The display device 1306 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1300 may include an audio output device 1308 (or corresponding interface circuitry, as discussed above). The audio output device 1308 may include any embedded or wired or wirelessly connected external device that generates an audible indicator, such speakers, headsets, or earbuds.

The electrical device 1300 may include an audio input device 1324 (or corresponding interface circuitry, as discussed above). The audio input device 1324 may include any embedded or wired or wirelessly connected device that generates a signal representative of a sound, such as microphones, microphone arrays, or digital instruments (e.g., instruments having a musical instrument digital interface (MIDI) output). The electrical device 1300 may include a Global Navigation Satellite System (GNSS) device 1318 (or corresponding interface circuitry, as discussed above), such as a Global Positioning System (GPS) device. The GNSS device 1318 may be in communication with a satellite-based system and may determine a geolocation of the electrical device 1300 based on information received from one or more GNSS satellites, as known in the art.

The electrical device 1300 may include an other output device 1310 (or corresponding interface circuitry, as discussed above). Examples of the other output device 1310 may include an audio codec, a video codec, a printer, a wired or wireless transmitter for providing information to other devices, or an additional storage device.

The electrical device 1300 may include another input device 1320 (or corresponding interface circuitry, as discussed above). Examples of the other input device 1320 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1300 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1300 may be any other electronic device that processes data. In some embodiments, the electrical device 1300 may comprise multiple discrete physical components. Given the range of devices that the electrical device 1300 can be manifested as in various embodiments, in some embodiments, the electrical device 1300 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an apparatus comprising: a core layer; buildup layers on a first side of the core layer, the buildup layers comprising a plurality of metallization layers; and a device within an opening in the core layer and comprising: a first assembly comprising: a layer comprising capacitors, wherein a plane of the layer comprising capacitors is substantially orthogonal to a plane of the core layer; and conductive traces on the layer comprising capacitors, the conductive traces connecting the capacitors to first conductive contacts in the buildup layers; and a second assembly coupled to the first circuit component assembly and comprising one or more conductive traces within a magnetic material, the one or more conductive traces connected to second conductive contacts in the buildup layers.

Example 2 includes the subject matter of Example 1, wherein the layer comprising capacitors comprises redistribution layers connecting the capacitors to the conductive traces of the first assembly.

Example 3 includes the subject matter of any one of Examples 1-2, wherein the capacitors comprise deep trench capacitors (DTCs) or metal-in-metal (MIM) capacitors.

Example 4 includes the subject matter of any one of Examples 1-3, wherein a plane of the conductive traces of the first assembly is substantially orthogonal to the plane of the core layer and a plane of the conductive traces of the second assembly is substantially orthogonal to the plane of the core layer.

Example 5 includes the subject matter of any one of Examples 1-4, wherein the conductive traces of the first assembly each comprise a contact portion at the first side of the core layer that is larger in area, with respect to the plane of the core layer, than an area of remaining portions of the trace.

Example 6 includes the subject matter of any one of Examples 1-5, wherein the buildup layers are first buildup layers on a first side of the core layer, the substrate further comprises second buildup layers on a second side of the core layer opposite the first side, the conductive traces of the first assembly are connected to first conductive contacts in the second buildup layers, and the conductive traces of the second assembly are connected to second conductive contacts in the second buildup layers.

Example 7 includes the subject matter of any one of Examples 1-6, wherein the device further comprises a third assembly coupled to the first assembly and the second assembly, the third assembly comprising: a layer comprising capacitors, wherein a plane of the layer comprising capacitors is substantially orthogonal to a plane of the core layer; and conductive traces on the layer comprising capacitors, the conductive traces connecting the capacitors to third conductive contacts in the buildup layers.

Example 8 includes the subject matter of any one of Examples 1-7, wherein the device further comprises a third assembly coupled to the first assembly and the second assembly, the third assembly comprising one or more conductive traces within a magnetic material, the one or more conductive traces connected to third conductive contacts in the buildup layers.

Example 9 includes the subject matter of any one of Examples 1-8, wherein the device further comprises a third assembly coupled to the first assembly and the second assembly, wherein the third assembly comprises: a layer comprising transistors; and conductive traces on the layer comprising transistors, the conductive traces connecting the capacitors to third conductive contacts in the buildup layers.

Example 10 is apparatus comprising: a core layer oriented in a first plane; buildup layers on a first side of the core layer, the buildup layers comprising a plurality of metallization layers; and a device embedded in the core layer and comprising: a first circuit component assembly comprising a layer of conductive traces in a second plane within 10 degrees of orthogonal to the first plane, at least one of the conductive traces connecting to a first conductive contact in the buildup layers; and a second circuit component assembly coupled to the first circuit component assembly and comprising a layer of conductive traces in a third plane within 10 degrees of orthogonal to the first plane and substantially parallel to the second plane, at least one of the conductive traces connecting to a second conductive contact in the buildup layers.

Example 11 includes the subject matter of Example 10, wherein the first circuit component assembly comprises a plurality of capacitors.

Example 12 includes the subject matter of Example 11, wherein the first circuit component assembly comprises a layer comprising capacitors, and the conductive traces of the first circuit component assembly are on the layer comprising capacitors.

Example 13 includes the subject matter of any one of Examples 10-12, wherein the second circuit component assembly comprises a magnetic material surrounding the conductive traces.

Example 14 includes the subject matter of any one of Examples 10-13, further comprising a third circuit component assembly coupled to the first circuit component assembly and the second circuit component assembly, the third circuit component assembly comprising a layer of conductive traces in a fourth plane that is within 10 degrees of orthogonal to the first plane and substantially parallel to the second plane and to the third plane.

Example 15 includes the subject matter of Example 14, wherein the third circuit component assembly comprises a plurality of capacitors.

Example 16 includes the subject matter of Example 14, wherein the third circuit component assembly comprises one or more transistors.

Example 17 includes the subject matter of Example 16, wherein the third circuit component assembly comprises a layer comprising the one or more transistors, and the conductive traces of the third circuit component assembly are on the layer comprising the one or more transistors.

Example 17.5 includes the subject matter of any preceding Example, wherein the apparatus further comprises an integrated circuit die coupled to buildup layers.

Example 18 is a system comprising: a package substrate comprising: a core layer; and first buildup layers on a first side of the core layer, the first buildup layers comprising a plurality of metallization layers; second buildup layers on a second side of the core layer, the second buildup layers comprising a plurality of metallization layers; and a device embedded in the core layer, the device comprising a stack of multiple circuit component assemblies, each circuit component assembly comprising a respective layer of conductive traces oriented in a planar direction that is substantially orthogonal (e.g., within 10 degrees of orthogonal) to a planar direction of the core layer, at least one conductive trace of each circuit component connected to a conductive contact in the first buildup layers or in the second buildup layers; and an integrated circuit die coupled to the package substrate.

Example 19 includes the subject matter of Example 18, wherein the device comprises: a first circuit component assembly comprising a layer comprising capacitors, wherein the conductive traces of the first circuit component assembly are on the layer comprising capacitors; and a second assembly comprising a magnetic material surrounding conductive traces.

Example 20 includes the subject matter of Example 19, wherein the device further comprises: a third circuit component assembly comprising a layer of transistors, wherein the conductive traces of the third circuit component assembly are on the layer of transistors.

Example 21 includes the subject matter of any one of Examples 18-20, further comprising a main circuit board, the package substrate coupled to the main circuit board.

Example 22 includes the subject matter of any one of Examples 18-21, wherein the device is a voltage regulation circuit to receive input power and provide output power to the integrated circuit die.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

Further, concepts described herein are illustrated by way of example and not by way of limitation in the accompanying Figures. For simplicity and clarity of illustration, elements illustrated in the Figures might not be necessarily drawn to scale. Where considered appropriate, reference labels may have been repeated between certain Figures to indicate corresponding or analogous elements.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

In various embodiments, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

In various embodiments, the term “adjacent” refers to layers or components that are in physical contact with each other. That is, there is no layer or component between the stated adjacent layers or components. For example, a layer X that is adjacent to a layer Y refers to a layer that is in physical contact with layer Y.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An apparatus comprising:
a core layer;
buildup layers on a first side of the core layer, the buildup layers comprising a plurality of metallization layers; and
a device within an opening in the core layer and comprising:
a first assembly comprising:
a layer comprising capacitors, wherein a plane of the layer comprising capacitors is substantially orthogonal to a plane of the core layer; and
conductive traces on the layer comprising capacitors, the conductive traces connecting the capacitors to first conductive contacts in the buildup layers; and
a second assembly coupled to the first assembly and comprising one or more conductive traces within a magnetic material, the one or more conductive traces connected to second conductive contacts in the buildup layers.

2. The apparatus of claim 1, wherein the layer comprising capacitors comprises redistribution layers connecting the capacitors to the conductive traces of the first assembly.

3. The apparatus of claim 1, wherein the capacitors comprise deep trench capacitors (DTCs) or metal-in-metal (MIM) capacitors.

4. The apparatus of claim 1, wherein a plane of the conductive traces of the first assembly is substantially orthogonal to the plane of the core layer and a plane of the conductive traces of the second assembly is substantially orthogonal to the plane of the core layer.

5. The apparatus of claim 1, wherein the conductive traces of the first assembly each comprise a contact portion at the first side of the core layer that is larger in area, with respect to the plane of the core layer, than an area of remaining portions of the trace.

6. The apparatus of claim 1, wherein the buildup layers are first buildup layers on a first side of the core layer, the apparatus further comprises second buildup layers on a second side of the core layer opposite the first side, the conductive traces of the first assembly are connected to first conductive contacts in the second buildup layers, and the conductive traces of the second assembly are connected to second conductive contacts in the second buildup layers.

7. The apparatus of claim 1, wherein the device further comprises a third assembly coupled to the first assembly and the second assembly, the third assembly comprising:
a layer comprising capacitors, wherein a plane of the layer comprising capacitors is substantially orthogonal to a plane of the core layer; and
conductive traces on the layer comprising capacitors, the conductive traces connecting the capacitors to third conductive contacts in the buildup layers.

8. The apparatus of claim 1, wherein the device further comprises a third assembly coupled to the first assembly and the second assembly, the third assembly comprising one or more conductive traces within a magnetic material, the one or more conductive traces connected to third conductive contacts in the buildup layers.

9. The apparatus of claim 1, wherein the device further comprises a third assembly coupled to the first assembly and the second assembly, wherein the third assembly comprises:
a layer comprising transistors; and
conductive traces on the layer comprising transistors, the conductive traces connecting the capacitors to third conductive contacts in the buildup layers.

10. An apparatus comprising:
a core layer oriented in a first plane;
buildup layers on a first side of the core layer, the buildup layers comprising a plurality of metallization layers; and
a device embedded in the core layer and comprising:
a first circuit component assembly comprising a layer of conductive traces in a second plane within 10 degrees of orthogonal to the first plane, at least one of the conductive traces connecting to a first conductive contact in the buildup layers; and
a second circuit component assembly coupled to the first circuit component assembly and comprising a layer of conductive traces in a third plane within 10 degrees of orthogonal to the first plane and substantially parallel to the second plane, at least one of the conductive traces connecting to a second conductive contact in the buildup layers.

11. The apparatus of claim 10, wherein the first circuit component assembly comprises a plurality of capacitors.

12. The apparatus of claim 11, wherein the first circuit component assembly comprises a layer comprising capacitors, and the conductive traces of the first circuit component assembly are on the layer comprising capacitors.

13. The apparatus of claim 10, wherein the second circuit component assembly comprises a magnetic material surrounding the conductive traces.

14. The apparatus of claim 10, further comprising a third circuit component assembly coupled to the first circuit component assembly and the second circuit component assembly, the third circuit component assembly comprising a layer of conductive traces in a fourth plane within 10 degrees of orthogonal to the first plane and substantially parallel to the second plane and to the third plane.

15. The apparatus of claim 14, wherein the third circuit component assembly comprises a plurality of capacitors.

16. The apparatus of claim 14, wherein the third circuit component assembly comprises one or more transistors.

17. The apparatus of claim 16, wherein the third circuit component assembly comprises a layer comprising the one or more transistors, and the conductive traces of the third circuit component assembly are on the layer comprising the one or more transistors.

18. A system comprising:
a package substrate comprising:
a core layer; and
first buildup layers on a first side of the core layer, the first buildup layers comprising a plurality of metallization layers;
second buildup layers on a second side of the core layer, the second buildup layers comprising a plurality of metallization layers; and
a device embedded in the core layer, the device comprising a stack of multiple circuit component assemblies, each circuit component assembly comprising a respective layer of conductive traces oriented in a planar direction that is substantially orthogonal to a planar direction of the core layer, at least one conductive trace of each circuit component connected to a conductive contact in the first buildup layers or in the second buildup layers; and
an integrated circuit die coupled to the package substrate.

19. The system of claim 18, wherein the device comprises:
a first circuit component assembly comprising a layer comprising capacitors, wherein the conductive traces of the first circuit component assembly are on the layer comprising capacitors; and
a second assembly comprising a magnetic material surrounding conductive traces.

20. The system of claim 19, wherein the device further comprises:
a third circuit component assembly comprising a layer of transistors, wherein the conductive traces of the third circuit component assembly are on the layer of transistors.
